(19) United States
(12) Patent Application Publication
(10) Pub. No.: US 2024/0186144 A1
(43) Pub. Date: Jun. 6, 2024

(54) METHODS OF FORMING CARBONACEOUS MEMBRANE WITH FREE-STANDING FORM

(71) Applicants: Fraunhofer USA, Inc., Plymouth, MI (US); The Research Foundation for the State University of New York, Amherst, NY (US)

(72) Inventors: Matthias Muehle, Howell, MI (US); Jung-Hun Seo, Buffalo, NY (US); Dmitry Shinyavskiy, Buffalo, NY (US)

(21) Appl. No.: 18/075,345

(22) Filed: Dec. 5, 2022

(51) Int. Cl. H01L 21/04

(52) U.S. Cl. CPC H01L 21/041; H01L 21/042

(57) ABSTRACT

A method for providing a carbonaceous membrane is disclosed. The method includes forming a sacrificial layer on a first substrate. The method includes forming a carbonaceous membrane on the sacrificial layer. The method includes removing the sacrificial layer, with a first surface of the carbonaceous membrane still facing the first substrate. The method includes completely removing the first substrate from the carbonaceous membrane. The method includes coupling the carbonaceous membrane to a second substrate.

### TECHNICAL FIELD

The present invention relates generally to methods for forming a free-standing carbonaceous membrane.

### BACKGROUND

Due to its unique combination of outstanding physical and chemical properties, such as wide band-gap, chemical inertness, the highest hardness and thermal conductivity, negative electron affinity, and biocompatibility, diamond (e.g., one of various carbonaceous materials) is considered promising for application in electronic and micro-electromechanical devices, thermal management solutions, biomedical sensors, electrochemical electrodes, and field electron emission (FEE) devices. For such a carbonaceous material to be reliably and efficiently used in any of the various applications, a process to form the carbonaceous material as a membrane with adjustable dimensions is commonly desirable.

### SUMMARY

In one aspect of the present disclosure, a method for providing a carbonaceous membrane is provided. The method includes forming a sacrificial layer on a first substrate; forming a carbonaceous membrane on the sacrificial layer; removing the sacrificial layer, with a first surface of the carbonaceous membrane still facing the first substrate; completely removing the first substrate from the carbonaceous membrane; and coupling the carbonaceous membrane to a second substrate.

The method may further include attaching the first surface of the carbonaceous membrane to the second substrate.

The method, prior to attaching the first surface of the carbonaceous membrane to the second substrate, may further include doping one or more regions of the carbonaceous membrane that are disposed along its opposite second surface.

The method, prior to attaching the first surface of the carbonaceous membrane to the second substrate, may further include etching one or more regions of the carbonaceous membrane that are disposed along its opposite second surface.

The method may further include flipping the carbonaceous membrane together with the first substrate; attaching a second surface of the carbonaceous membrane to the second substrate, the second surface being opposite to the first surface; and removing the first substrate.

The method, prior to flipping the carbonaceous membrane, may further include doping one or more regions of the carbonaceous membrane that are disposed along the second surface.

The method, prior to flipping the carbonaceous membrane, may further include etching one or more regions of the carbonaceous membrane that are disposed along the second surface.

The method, subsequently to removing the first substrate, may further include doping one or more regions of the carbonaceous membrane that are disposed along the first surface.

The method, subsequently to removing the first substrate, may further include etching one or more regions of the carbonaceous membrane that are disposed along the first surface.

The method may further include growing a nucleation layer between the sacrificial layer and the carbonaceous membrane; subsequently to removing the sacrificial layer, flipping the carbonaceous membrane together with the nucleation layer; and removing the nucleation layer.

The method may further include growing a nucleation layer between the sacrificial layer and the carbonaceous membrane; smoothing a second surface of the carbonaceous membrane, followed by removing the sacrificial layer, wherein the second surface is opposite to the first surface; flipping the carbonaceous membrane together with the nucleation layer; and removing the nucleation layer.

The method may further include increasing a thickness of the carbonaceous membrane on the sacrificial layer to form the carbonaceous membrane having a grain size that increases from the first surface to its opposite second surface; flipping the carbonaceous membrane together with the first substrate; attaching the second surface of the carbonaceous membrane to the second substrate; removing the first substrate; and thinning down the carbonaceous membrane from its first surface.

The carbonaceous membrane may include a material selected from the group consisting of: a sp³ containing carbonaceous material, the sp³ containing carbonaceous material comprising at least one of a monocrystalline diamond, a randomly oriented diamond, a polycrystalline diamond, a microcrystalline diamond, nanocrystalline diamond, a ultrananocrystalline diamond, a diamond epilayer/film on a heteroepitaxial substrate, and combination thereof.

In another aspect of the present disclosure, a method for providing a carbonaceous membrane is provided. The method includes forming a sacrificial layer on a first substrate; forming a carbonaceous membrane on the sacrificial layer, with a bottom surface of the carbonaceous membrane in contact with the sacrificial layer; removing the sacrificial layer; completely removing the first substrate from the carbonaceous membrane; and attaching the bottom surface of the carbonaceous membrane to a second substrate.

The carbonaceous membrane may include a material selected from the group consisting of: a sp³ containing carbonaceous material, the sp³ containing carbonaceous material comprising at least one of a monocrystalline diamond, a randomly oriented diamond, a polycrystalline diamond, a microcrystalline diamond, nanocrystalline diamond, a ultrananocrystalline diamond, a diamond epilayer/film on a heteroepitaxial substrate, and combination thereof.

The method may further include forming a doped or etched region along a top surface of the carbonaceous membrane.

In yet another aspect of the present disclosure, a method for providing a carbonaceous membrane is provided. The method includes forming a sacrificial layer on a first substrate; forming a carbonaceous membrane on the sacrificial layer, with a bottom surface of the carbonaceous membrane in contact with the sacrificial layer; removing the sacrificial layer; flipping the carbonaceous membrane; attaching a top surface of the carbonaceous membrane to a second substrate; and completely removing the first substrate from the carbonaceous membrane.

The carbonaceous membrane may include a material selected from the group consisting of: a sp³ containing carbonaceous material, the sp³ containing carbonaceous material comprising at least one of a monocrystalline diamond, a randomly oriented diamond, a polycrystalline diamond, a microcrystalline diamond, nanocrystalline diamond, a ultrananocrystalline diamond, a diamond epilayer/film on a heteroepitaxial substrate, and combination thereof.

The method, prior to flipping the carbonaceous membrane, may further include forming a doped or etched region along the top surface of the carbonaceous membrane.

The method may further include forming a doped or etched region along a bottom surface of the carbonaceous membrane.

It should be appreciated that all combinations of the foregoing concepts and additional concepts discussed in greater detail below (provided such concepts are not mutually inconsistent) are contemplated as being part of the subject matter disclosed herein. In particular, all combinations of claimed subject matter appearing at the end of this disclosure are contemplated as being part of the subject matter disclosed herein.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several implementations in accordance with the disclosure and are not, therefore, to be considered limiting of its scope, the disclosure will be described with additional specificity and detail through use of the accompanying drawings.

FIG. 1 illustrates a flowchart of an example method for forming a carbonaceous membrane, according to various embodiments of the present disclosure.

FIG. 2 illustrates a flowchart of an example method for forming a carbonaceous membrane, based on the method of FIG. 1, according to various embodiments of the present disclosure.

FIG. 3 illustrates a flowchart of an example method for forming a carbonaceous membrane, based on the method of FIG. 1, according to various embodiments of the present disclosure.

FIG. 4 illustrates a flowchart of an example method for forming a carbonaceous membrane, based on the method of FIG. 1, according to various embodiments of the present disclosure.

FIG. 5 illustrates a flowchart of an example method for forming a carbonaceous membrane, based on the method of FIG. 1, according to various embodiments of the present disclosure.

FIG. 6 illustrates a flowchart of an example method for forming a carbonaceous membrane, based on the method of FIG. 1, according to various embodiments of the present disclosure.

FIG. 7 illustrates a flowchart of an example method for forming a carbonaceous membrane, based on the method of FIG. 1, according to various embodiments of the present disclosure.

FIGS. 8, 9, and 10 illustrate example semiconductor devices each including a carbonaceous membrane, made by the method of FIG. 2, according to various embodiments of the present disclosure.

FIGS. 11, 12, and 13 illustrate example semiconductor devices each including a carbonaceous membrane, made by the method of FIG. 3, according to various embodiments of the present disclosure.

FIGS. 14, 15, and 16 illustrate example semiconductor devices each including a carbonaceous membrane, made by the method of FIG. 4, according to various embodiments of the present disclosure.

FIG. 17 illustrates an example semiconductor device including a carbonaceous membrane, made by the method of FIG. 5, according to various embodiments of the present disclosure.

FIG. 18 illustrates an example semiconductor device including a carbonaceous membrane, made by the method of FIG. 6, according to various embodiments of the present disclosure.

FIG. 19 illustrates an example semiconductor device including a carbonaceous membrane, made by the method of FIG. 7, according to various embodiments of the present disclosure.

Reference is made to the accompanying drawings throughout the following detailed description. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

### DETAILED DESCRIPTION

A free-standing form of a carbonaceous material (e.g., a poly-crystalline diamond (PCD) thin film or membrane) has been widely used in various electronic and optoelectronic applications, particularly when reliable mechanical/thermal/electrical properties are also required. However, conventional approaches to fabricate such a PCD membrane may require an excessive etching process from the backside of a substrate to access the PCD membrane that is typically deposited on a frontside of the substrate. This conventional process has several limits and restrictions that prohibit the realization of a large-scale and high-quality PCD membrane, thus leading to a high production cost. As a result, most PCD membrane-based applications are expensive and some applications have switched to alternative materials even though the properties of those material are not comparable with the carbonaceous material.

The present disclosure provides various embodiments of methods for making a large-scale and high-quality PCD membrane that can have a free-standing and transferrable form. In brief overview, a sacrificial layer (e.g., a silicon dioxide (SiO₂) layer) is first formed on a (e.g., silicon (Si)) substrate, followed by forming a PCD layer, according to various embodiments. Next, the sacrificial layer is selectively removed to physically separate the PCD layer from the substrate. In some embodiments, such a separated PCD layer is sometimes referred to as a PCD membrane. Given that this PCD membrane can be transferred using one of various micro-transfer printing techniques, the PCD membrane can be easily placed/located at any desired location to form a PCD membrane-based heterostructure. For example, the PCD membrane, fabricated by the method disclosed herein, can be integrated into any suitable electronic/mechanical/thermal/optoelectronic device.

A PCD membrane can be used in various fields in novel electronics and bioelectronics. For example, PCD membranes can be used as active semiconductor materials to build flexible electronic devices such as, for example, PCD membrane field-effect transistors, PCD membrane based photo-transistors, PCD membrane p+/p− or Schottky junction based photodetectors, PCD membrane based quantum sensors, PCD membrane based thermal sensors, PCD membrane based pressure sensors, PCD membrane based radiation sensors, that have excellent mechanical and electrical properties simultaneously. Also, the transfer-printed PCD membrane can be used as a heat dissipater, thus Joule heating can be effectively removed from the surface of the circuit or system. Heavily doped PCD membranes can be used as a reliable electrode for various photoelectrochemical applications including a battery, water splitting for hydrogen-fuel cell and other chemical reaction processes. Such a doped PCD membrane (sometimes referred to as boron doped PCD membrane (BDD)) can be used as electrode material for electrochemical oxidation (and reduction) in sensing and treatment of water, which includes sensing for heavy metals, such as lead, cadmium, arsenic. A doped PCD membrane is also a common choice for electrochemical degradation of PFAS compounds and nitrogen-based fertilizers. The doped PCD membrane can be used to treat leachates as well as ground water. Toward bioelectronics, PCD membranes can be used as highly-reliable electrodes for various flexible implantable medical devices as opposed to conventional metal electrodes.

Before turning to the figures, which illustrate certain exemplary embodiments in detail, it should be understood that the present disclosure is not limited to the details or methodology set forth in the description or illustrated in the figures. It should also be understood that the terminology used herein is for the purpose of description only and should not be regarded as limiting.

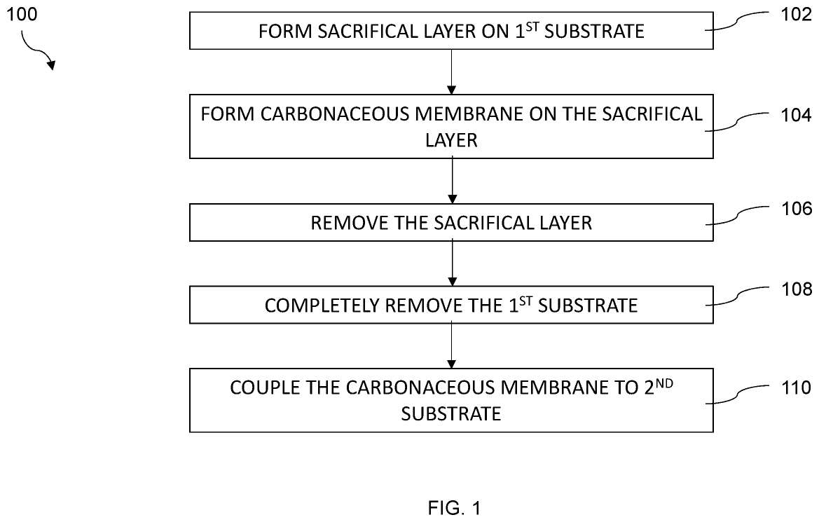

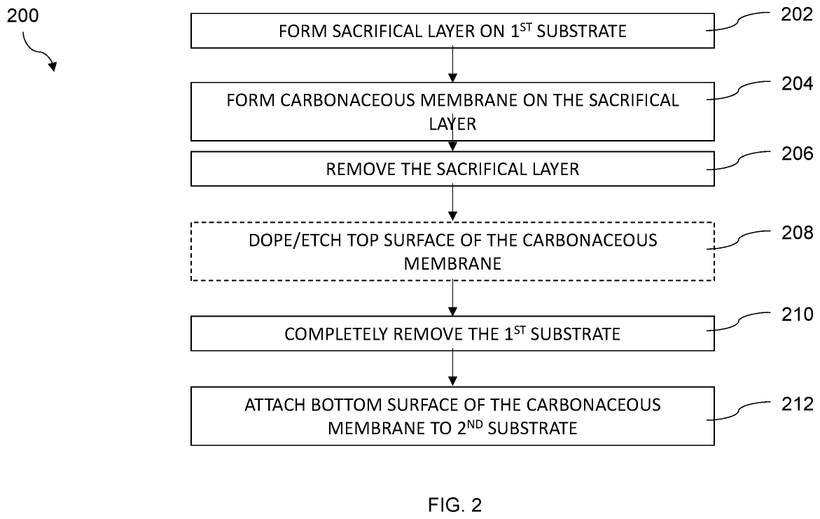

FIG. 1 illustrates a flowchart of an example method 100 for forming a carbonaceous membrane in a free-standing form. It is noted that the method 100 is merely a general example, and is not intended to limit the present disclosure. For example, based on the method 100, methods 200, 300, 400, 500, 600, and 700 illustrated in FIGS. 2, 3, 4, 5, 6, and 7, respectively, describe various other approaches to form a free-standing carbonaceous membrane. Accordingly, it is understood that additional operations may be provided before, during, and after the method 100 of FIG. 1 (as illustrated in FIG. 2 to FIG. 7), and that some other operations may only be briefly described herein.

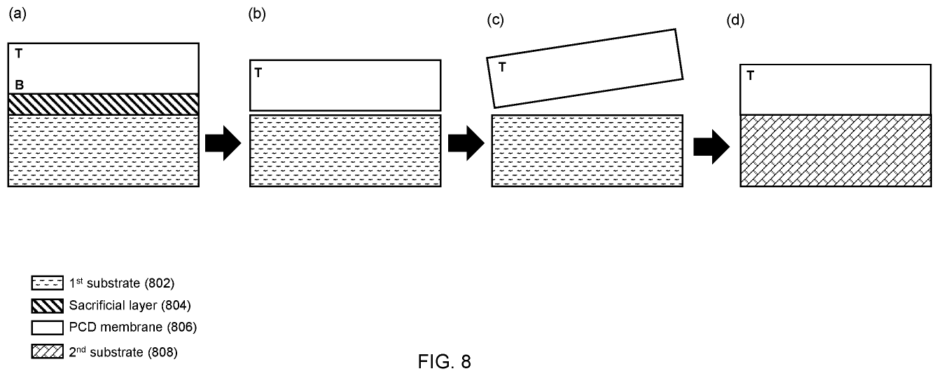

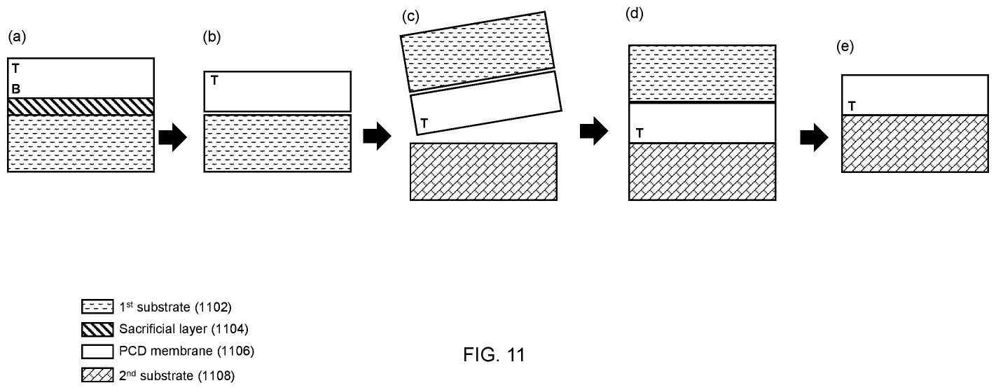

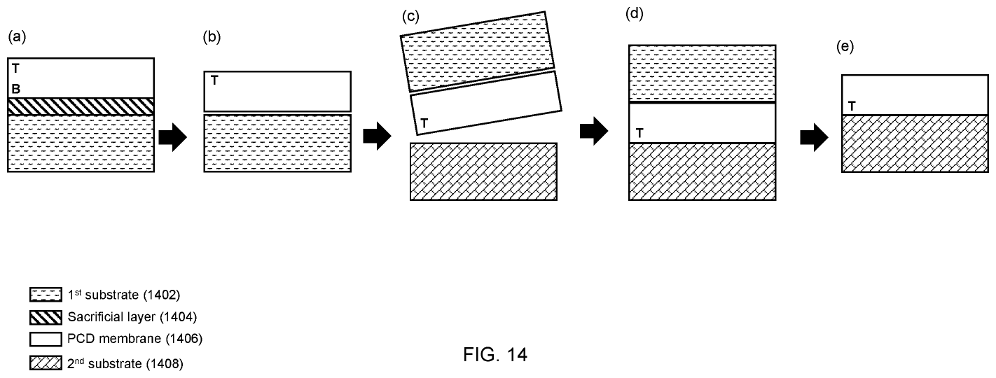

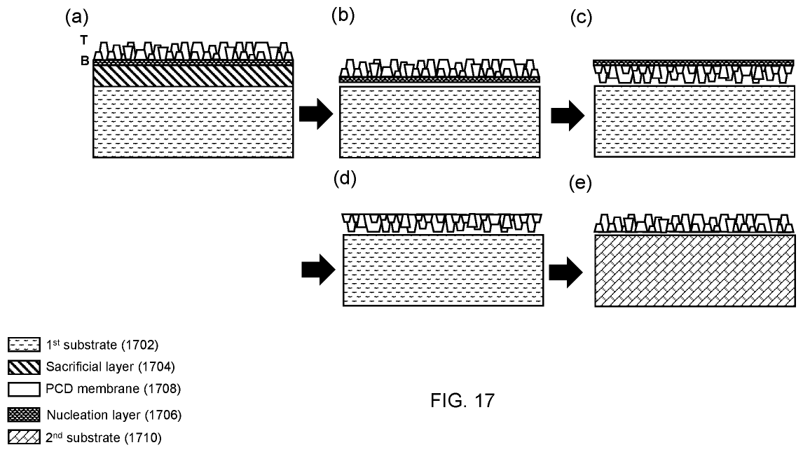

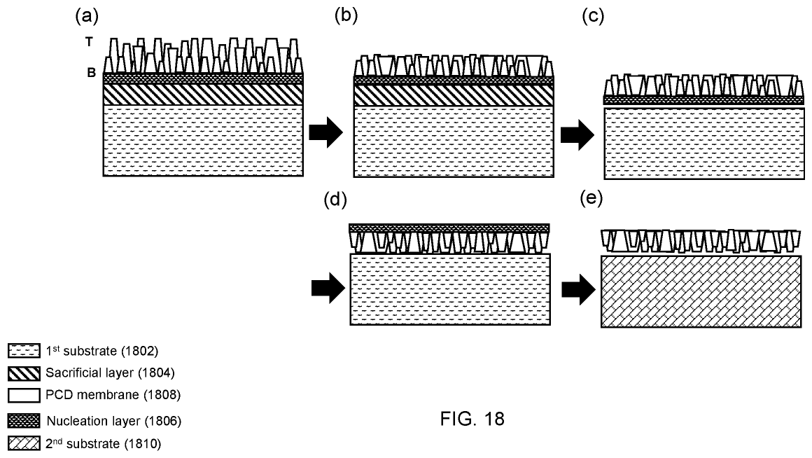

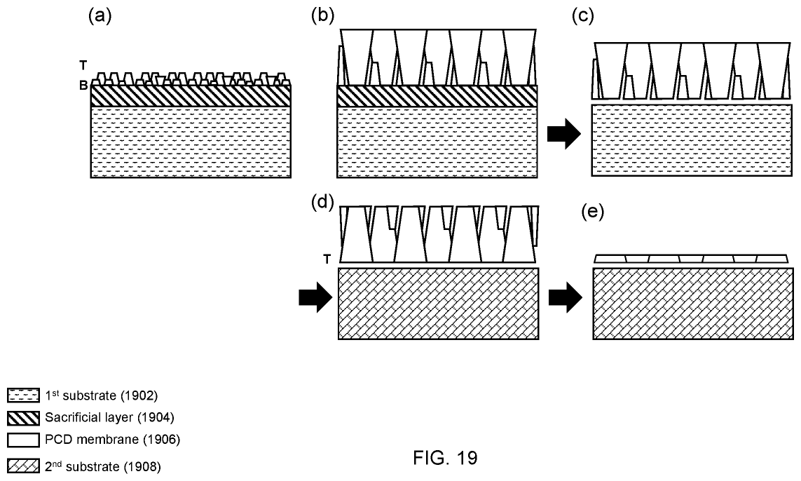

In various embodiments, operations of each of the methods 200 to 700 may be associated with cross-sectional views of an example semiconductor device at various fabrication stages as shown in FIGS. 8 to 19, respectively, which will be discussed in further detail below. For example, the method 200 may correspond to the semiconductor device shown in FIGS. 8 to 10; the method 300 may correspond to the semiconductor device shown in FIGS. 11 to 13; the method 400 may correspond to the semiconductor device shown in FIGS. 14 to 16; the method 500 may correspond to the semiconductor device shown in FIG. 17; the method 600 may correspond to the semiconductor device shown in FIG. 18; and the method 700 may correspond to the semiconductor device shown in FIG. 19. It should be understood that the semiconductor device, shown in FIGS. 8 to 19, may include a number of other devices such as inductors, fuses, capacitors, coils, etc., while remaining within the scope of the present disclosure.

Referring first to FIG. 1, in brief overview, the method 100 starts with operation 102 of forming a sacrificial layer on a first substrate. The method 100 continues to operation 104 of forming a carbonaceous membrane on the sacrificial layer. The method 100 continues to operation 106 of removing the sacrificial layer. The method 100 continues to operation 108 of completely removing the first substrate. The method 100 continues to operation 110 of coupling the carbonaceous membrane to a second substrate.

Referring next to FIG. 2, the method 200 starts with operation 202 of forming a sacrificial layer on a first substrate. The method 200 continues to operation 204 of forming a carbonaceous membrane on the sacrificial layer. The method 200 continues to operation 206 of removing the sacrificial layer. The method 200 continues to optional operation 208 of doping or etching one or more regions along a top surface of the carbonaceous membrane. The method 200 continues to operation 210 of completely removing the first substrate. The method 200 continues to operation 212 of attaching a bottom surface of the carbonaceous membrane to a second substrate.

Corresponding to operation 202 and the following operation 204, step (a) of each of FIGS. 8 to 10 illustrates a carbonaceous membrane (e.g., 806, 906, 1006) formed on a first substrate (e.g., 802, 902, 1002) with a sacrificial layer (e.g., 804, 904, 1004) disposed therebetween, according to some embodiments of the present disclosure.

The first substrate (e.g., 802, 902, 1002), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The first substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the first substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. For example, the first substrate may include gallium arsenic functioning as a substrate and AlGaAs functioning as a sacrificial layer that can be selectively removed later. In some other embodiments, the material of the first substrate may include magnesium oxide; sapphire; or combinations thereof.

The sacrificial layer (e.g., 804, 904, 1004) may be grown as a silicon oxide layer on the first substrate. The sacrificial layer may be formed over the first substrate through an oxidation process and/or a deposition process (e.g., atomic layer deposition (ALD), chemical vapor deposition (CVD), physical vapor deposition (PVD), etc.). It should be understood that any of various other oxidized sacrificial layers can be formed on the first substrate, while remaining within the scope of the present disclosure.

Upon forming the sacrificial layer, the carbonaceous membrane (e.g., 806, 906, 1006), comprising one or more carbonaceous materials (e.g., poly-crystalline diamond), is further formed over the sacrificial layer. Such a carbonaceous membrane may herein be referred to as PCD membrane 806, 906, or 1006. As shown, the PCD membrane has a bottom surface (labeled with “B”) contacting the sacrificial layer and a top surface (labeled with “T”) opposite to the bottom surface. In some other embodiments, the carbonaceous material of the PCD membrane may include a sp³ containing carbonaceous material such as, for example, monocrystalline diamond, randomly oriented diamond (such as, but not limited to, microcrystalline diamond, nanocrystalline diamond, and ultrananocrystalline diamond), diamond epilayer/film on a heteroepitaxial substrate, or a sp² containing carbonaceous material, for example, graphene or graphite, any other suitable substrate, or a combination thereof. The carbonaceous membrane may be grown on the sacrificial layer through one of various deposition processes (e.g., atomic layer deposition (ALD), chemical vapor deposition (CVD), physical vapor deposition (PVD), etc.). As mentioned above, the first substrate can be in the form of wafers, for example, having a diameter of 3 inches, 4 inches, 6 inches, 8 inches, or 12 inches, inclusive, or have any other shape or size. Accordingly, the carbonaceous membrane can have a diameter similar to the underlying first substrate.

Corresponding to operation 206, step (b) of each of FIGS. 8 to 10 illustrates that the sacrificial layer (e.g., 804, 904, 1004) is removed so as to physically separate the PCD membrane (e.g., 806, 906, 1006) from the first substrate (e.g., 802, 902, 1002), according to some embodiments of the present disclosure. In the example where the sacrificial layer is formed of silicon oxide, the sacrificial layer may be removed through a wet etching process, for example, by applying diluted hydrofluoric acid over the workpiece. After removing the sacrificial layer, the PCD membrane may gently sit on the first substrate, i.e., with the bottom surface of the PCD membrane still facing the first substrate.

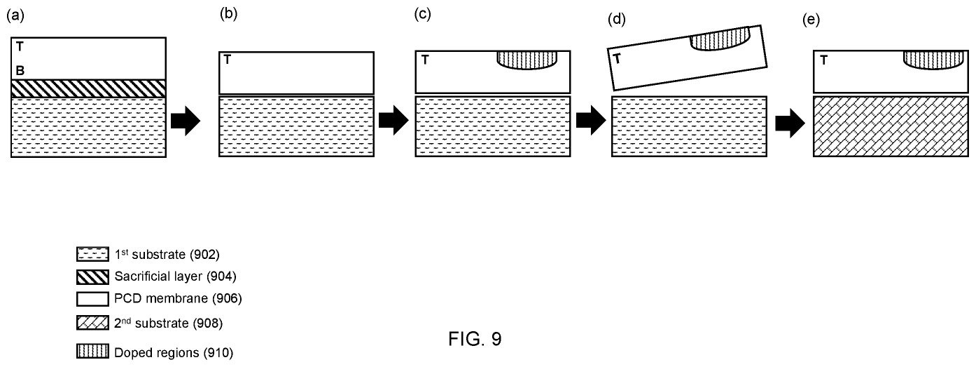

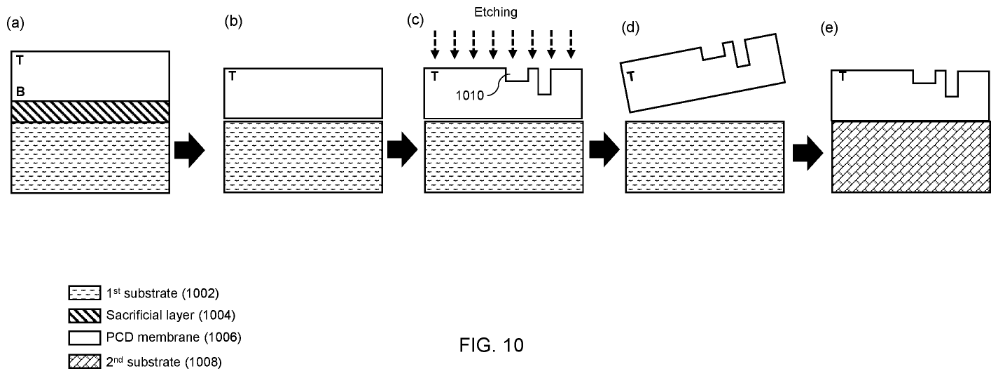

Corresponding to optional operation 208, step (c) of each of FIGS. 9 and 10 illustrates that a top surface of the PCD membrane (e.g., 906, 1006) has one or more doped or etched regions, according to some embodiments of the present disclosure. In FIG. 9, one or more regions (e.g., 910) along the top surface of the PCD membrane may be doped; and similarly in FIG. 10, one or more regions (e.g., 1010) along the top surface of the PCD membrane may be etched.

Corresponding to operation 210, step (c) of FIG. 8 and step (d) of each of FIGS. 9 to 10 illustrate that the first substrate (e.g., 802, 902, 1002) is completely removed from the PCD membrane (e.g., 806, 906, 1006), according to some embodiments of the present disclosure. Upon removing the sacrificial layer, the PCD membrane can be picked through various microfabrication techniques known in the art, so as to completely remove the first substrate from the PCD membrane.

Corresponding to operation 212, step (d) of FIG. 8 and step (e) of each of FIGS. 9 to 10 illustrate that the bottom surface of the PCD membrane (e.g., 806, 906, 1006) is attached to a second substrate (e.g., 808, 908, 1008), according to some embodiments of the present disclosure.

The second substrate (e.g., 808, 908, 1008), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The second substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the second substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. For example, the first substrate may include gallium arsenic functioning as a substrate and AlGaAs functioning as a sacrificial layer that can be selectively removed later. In some other embodiments, the material of the second substrate may include magnesium oxide; sapphire; or combinations thereof.

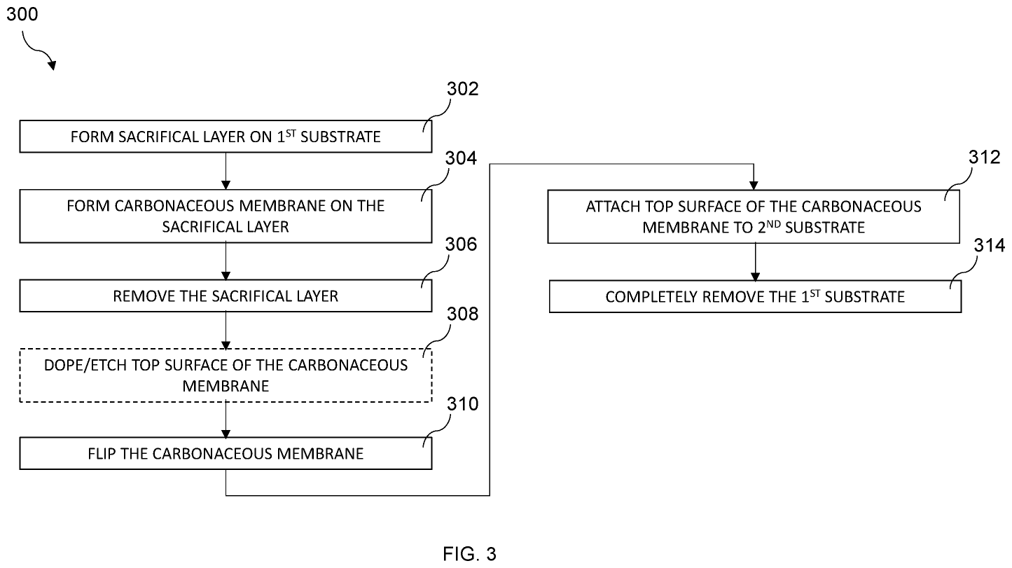

Referring next to FIG. 3, the method 300 starts with operation 302 of forming a sacrificial layer on a first substrate. The method 300 continues to operation 304 of forming a carbonaceous membrane on the sacrificial layer. The method 300 continues to operation 306 of removing the sacrificial layer. The method 300 continues to optional operation 308 of doping or etching one or more regions along a top surface of the carbonaceous membrane. The method 300 continues to operation 310 of flipping the carbonaceous membrane. The method 300 continues to operation 312 of attaching a top surface of the carbonaceous membrane to a second substrate. The method 300 continues to operation 314 of completely removing the first substrate.

Corresponding to operation 302 and the following operation 304, step (a) of each of FIGS. 11 to 13 illustrates a carbonaceous membrane (e.g., 1106, 1206, 1306) formed on a first substrate (e.g., 1102, 1202, 1302) with a sacrificial layer (e.g., 1104, 1204, 1304) disposed therebetween, according to some embodiments of the present disclosure.

The first substrate (e.g., 1102, 1202, 1302), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The first substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the first substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. For example, the first substrate may include gallium arsenic functioning as a substrate and AlGaAs functioning as a sacrificial layer that can be selectively removed later. In some other embodiments, the material of the first substrate may include magnesium oxide; sapphire; or combinations thereof.

The sacrificial layer (e.g., 1104, 1204, 1304) may be grown as a silicon oxide layer on the first substrate. The sacrificial layer may be formed over the first substrate through an oxidation process and/or a deposition process (e.g., atomic layer deposition (ALD), chemical vapor deposition (CVD), physical vapor deposition (PVD), etc.). It should be understood that any of various other oxidized sacrificial layers can be formed on the first substrate, while remaining within the scope of the present disclosure.

Upon forming the sacrificial layer, the carbonaceous membrane (e.g., 1106, 1206, 1306), comprising one or more carbonaceous materials (e.g., poly-crystalline diamond), is further formed over the sacrificial layer. Such a carbonaceous membrane may herein be referred to as PCD membrane 1106, 1206, or 1306. As shown, the PCD membrane has a bottom surface (labeled with “B”) contacting the sacrificial layer and a top surface (labeled with “T”) opposite to the bottom surface. In some other embodiments, the carbonaceous material of the PCD membrane may include a sp³ containing carbonaceous material such as, for example, monocrystalline diamond, randomly oriented diamond (such as, but not limited to, microcrystalline diamond, nanocrystalline diamond, and ultrananocrystalline diamond), diamond epilayer/film on a heteroepitaxial substrate, or a sp² containing carbonaceous material, for example, graphene or graphite, any other suitable substrate, or a combination thereof. The carbonaceous membrane may be grown on the sacrificial layer through one of various deposition processes (e.g., atomic layer deposition (ALD), chemical vapor deposition (CVD), physical vapor deposition (PVD), etc.). As mentioned above, the first substrate can be in the form of wafers, for example, having a diameter of 3 inches, 4 inches, 6 inches, 8 inches, or 12 inches, inclusive, or have any other shape or size. Accordingly, the carbonaceous membrane can have a diameter similar to the underlying first substrate.

Corresponding to operation 306, step (b) of each of FIGS. 11 to 13 illustrates that the sacrificial layer (e.g., 1104, 1204, 1304) is removed so as to physically separate the PCD membrane (e.g., 1106, 1206, 1306) from the first substrate (e.g., 1102, 1202, 1302), according to some embodiments of the present disclosure. In the example where the sacrificial layer is formed of silicon oxide, the sacrificial layer may be removed through a wet etching process, for example, by applying diluted hydrofluoric acid over the workpiece. After removing the sacrificial layer, the PCD membrane may gently sit on the first substrate, i.e., with the bottom surface of the PCD membrane still facing the first substrate.

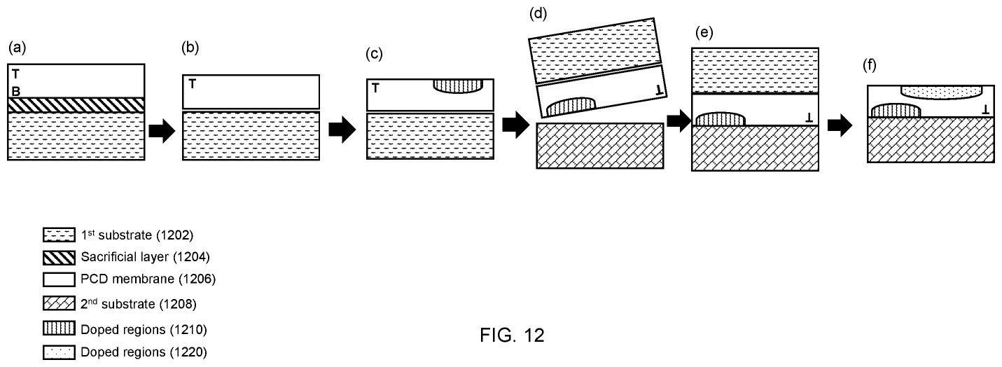

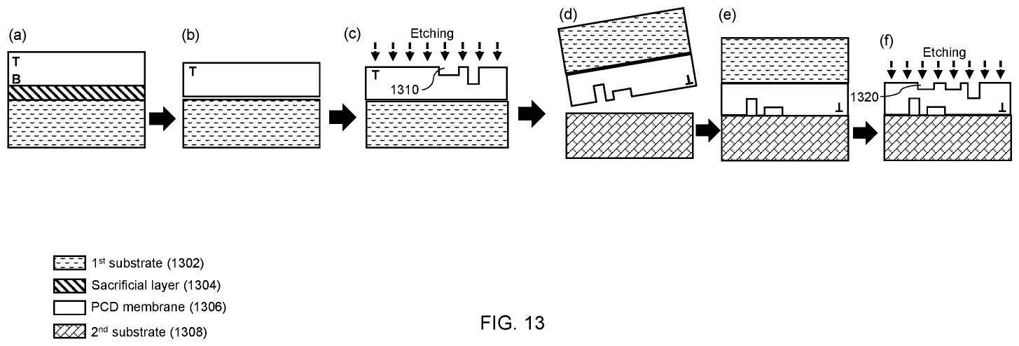

Corresponding to optional operation 308, step (c) of each of FIGS. 12 and 13 illustrates that a top surface of the PCD membrane (e.g., 1206, 1306) has one or more doped or etched regions, according to some embodiments of the present disclosure. In FIG. 12, one or more regions (e.g., 1210) along the top surface of the PCD membrane may be doped; and similarly in FIG. 13, one or more regions (e.g., 1310) along the top surface of the PCD membrane may be etched.

Corresponding to operation 310, step (c) of FIG. 11 and step (d) of each of FIGS. 12 to 13 illustrate that the PCD membrane (e.g., 1106, 1206, 1306), together with the first substrate (e.g., 1102, 1202, 1302), are flipped, according to some embodiments of the present disclosure.

Corresponding to operation 312, step (d) of FIG. 11 and step (e) of each of FIGS. 12 to 13 illustrate that the top surface of the PCD membrane (e.g., 1106, 1206, 1306) is attached to a second substrate (e.g., 1108, 1208, 1308), according to some embodiments of the present disclosure.

The second substrate (e.g., 1108, 1208, 1308), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The second substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the second substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some other embodiments, the material of the second substrate may include magnesium oxide; sapphire; or combinations thereof.

Corresponding to operation 314, step (e) of FIG. 11 and step (f) of each of FIGS. 12 to 13 illustrate that the first substrate (e.g., 1102, 1202, 1302) is completely removed from the PCD membrane (e.g., 1106, 1206, 1306), according to some embodiments of the present disclosure. In some embodiments, the bottom surface of the PCD membrane may have one or more regions doped or etched. For example in FIG. 12, the PCD membrane 1206 has one or more doped regions 1220; and in FIG. 13, the PCD membrane 1306 has one or more etched regions 1320.

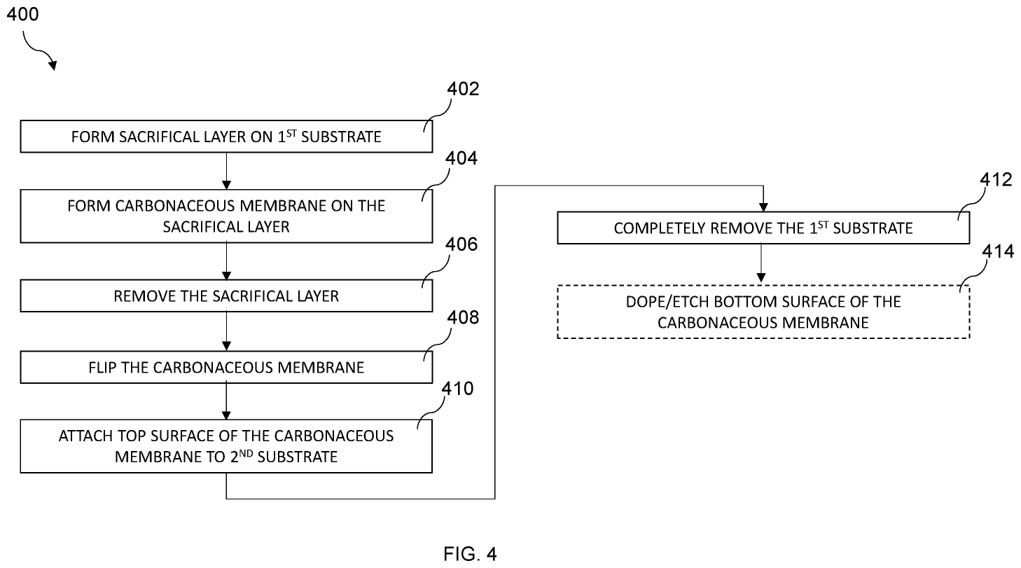

Referring next to FIG. 4, the method 400 starts with operation 402 of forming a sacrificial layer on a first substrate. The method 400 continues to operation 404 of forming a carbonaceous membrane on the sacrificial layer. The method 400 continues to operation 406 of removing the sacrificial layer. The method 400 continues to operation 408 of flipping the carbonaceous membrane. The method 400 continues to operation 410 of attaching a top surface of the carbonaceous membrane to a second substrate. The method 400 continues to operation 412 of completely removing the first substrate. The method 400 continues to optional operation 414 of doping or etching one or more regions along a bottom surface of the carbonaceous membrane.

Corresponding to operation 402 and the following operation 404, step (a) of each of FIGS. 14 to 16 illustrates a carbonaceous membrane (e.g., 1406, 1506, 1606) formed on a first substrate (e.g., 1402, 1502, 1602) with a sacrificial layer (e.g., 1404, 1504, 1604) disposed therebetween, according to some embodiments of the present disclosure.

The first substrate (e.g., 1402, 1502, 1602), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The first substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the first substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. For example, the first substrate may include gallium arsenic functioning as a substrate and AlGaAs functioning as a sacrificial layer that can be selectively removed later. In some other embodiments, the material of the first substrate may include magnesium oxide; sapphire; or combinations thereof.

The sacrificial layer (e.g., 1404, 1504, 1604) may be grown as a silicon oxide layer on the first substrate. The sacrificial layer may be formed over the first substrate through an oxidation process and/or a deposition process (e.g., atomic layer deposition (ALD), chemical vapor deposition (CVD), physical vapor deposition (PVD), etc.). It should be understood that any of various other oxidized sacrificial layers can be formed on the first substrate, while remaining within the scope of the present disclosure.

Upon forming the sacrificial layer, the carbonaceous membrane (e.g., 1406, 1506, 1606), comprising one or more carbonaceous materials (e.g., poly-crystalline diamond), is further formed over the sacrificial layer. Such a carbonaceous membrane may herein be referred to as PCD membrane 1406, 1506, or 1606. As shown, the PCD membrane has a bottom surface (labeled with “B”) contacting the sacrificial layer and a top surface (labeled with “T”) opposite to the bottom surface. In some other embodiments, the carbonaceous material of the PCD membrane may include a sp³ containing carbonaceous material such as, for example, monocrystalline diamond, randomly oriented diamond (such as, but not limited to, microcrystalline diamond, nanocrystalline diamond, and ultrananocrystalline diamond), diamond epilayer/film on a heteroepitaxial substrate, or a sp² containing carbonaceous material, for example, graphene or graphite, any other suitable substrate, or a combination thereof. The carbonaceous membrane may be grown on the sacrificial layer through one of various deposition processes (e.g., atomic layer deposition (ALD), chemical vapor deposition (CVD), physical vapor deposition (PVD), etc.). As mentioned above, the first substrate can be in the form of wafers, for example, having a diameter of 3 inches, 4 inches, 6 inches, 8 inches, or 12 inches, inclusive, or have any other shape or size. Accordingly, the carbonaceous membrane can have a diameter similar to the underlying first substrate.

Corresponding to operation 406, step (b) of each of FIGS. 14 to 16 illustrates that the sacrificial layer (e.g., 1404, 1504, 1604) is removed so as to physically separate the PCD membrane (e.g., 1406, 1506, 1606) from the first substrate (e.g., 1402, 1502, 1602), according to some embodiments of the present disclosure. In the example where the sacrificial layer is formed of silicon oxide, the sacrificial layer may be removed through a wet etching process, for example, by applying diluted hydrofluoric acid over the workpiece. After removing the sacrificial layer, the PCD membrane may gently sit on the first substrate, i.e., with the bottom surface of the PCD membrane still facing the first substrate.

Corresponding to operation 408, step (c) of each of FIGS. 14 to 16 illustrates that the PCD membrane (e.g., 1406, 1506, 1606), together with the first substrate (e.g., 1402, 1502, 1602), are flipped, according to some embodiments of the present disclosure.

Corresponding to operation 410, step (d) of each of FIGS. 14 to 16 illustrate that the top surface of the PCD membrane (e.g., 1406, 1506, 1606) is attached to a second substrate (e.g., 1408, 1508, 1608), according to some embodiments of the present disclosure.

The second substrate (e.g., 1408, 1508, 1608), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The second substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the second substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some other embodiments, the material of the second substrate may include magnesium oxide; sapphire; or combinations thereof.

Corresponding to operation 412, step (e) of each of FIGS. 14 to 16 illustrate that the first substrate (e.g., 1402, 1502, 1602) is completely removed from the PCD membrane (e.g., 1406, 1506, 1606), according to some embodiments of the present disclosure.

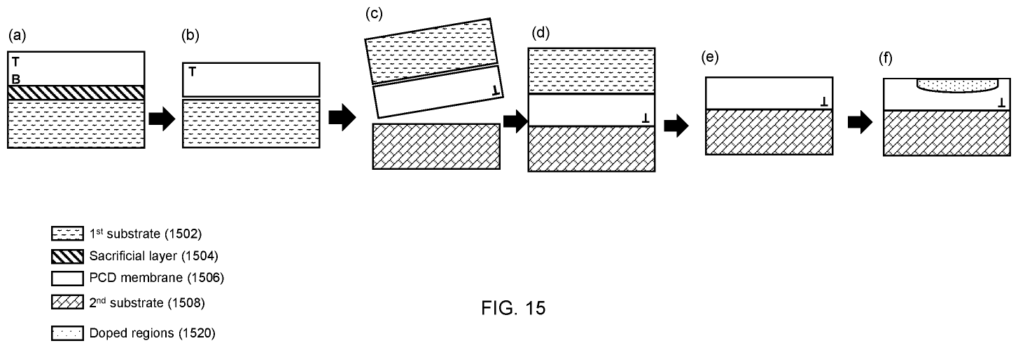

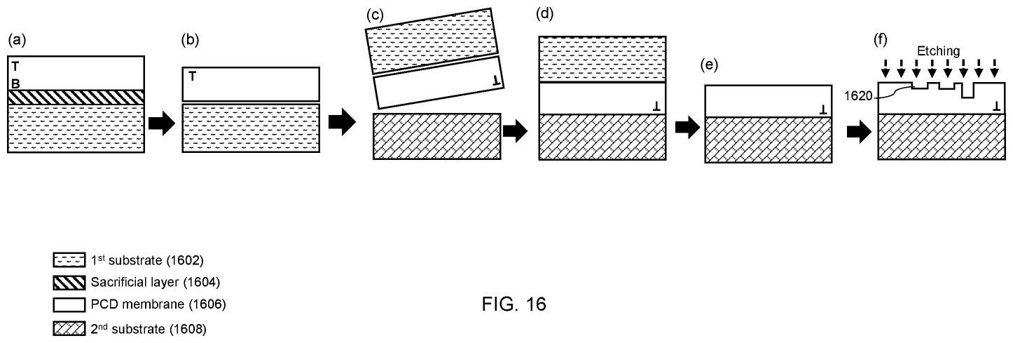

Corresponding to optional operation 414, step (f) of each of FIGS. 15 and 16 illustrates that the bottom surface of the PCD membrane (e.g., 1606, 1606) has one or more doped or etched regions, according to some embodiments of the present disclosure. In FIG. 15, one or more regions (e.g., 1520) along the bottom surface of the PCD membrane may be doped; and similarly in FIG. 16, one or more regions (e.g., 1620) along the top surface of the PCD membrane may be etched.

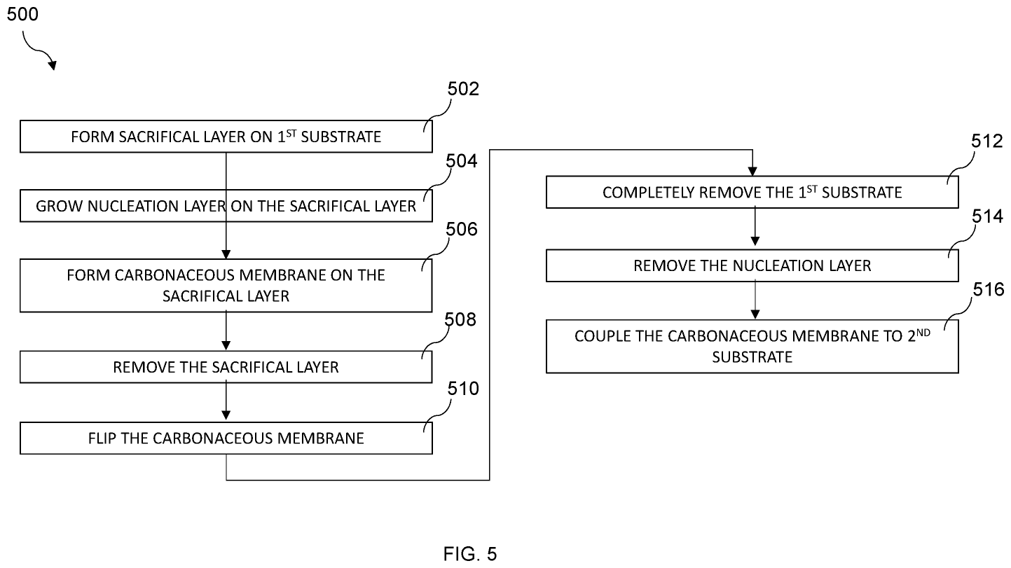

Referring next to FIG. 5, the method 500 starts with operation 502 of forming a sacrificial layer on a first substrate. The method 500 continues to operation 504 of forming a nucleation layer on the sacrificial layer. The method 500 continues to operation 506 of forming a carbonaceous membrane on the nucleation layer. The method 500 continues to operation 508 of removing the sacrificial layer. The method 500 continues to operation 510 of flipping the carbonaceous membrane. The method 500 continues to operation 512 of completely removing the first substrate. The method 500 continues to operation 514 of removing the nucleation layer. The method 500 continues to operation 516 of coupling the carbonaceous membrane to a second substrate.

Corresponding to operation 502 and the following operations 504 and 506, step (a) of FIG. 17 illustrates a sacrificial layer (e.g., 1704) first formed on a first substrate 1702, with a nucleation layer (e.g., 1706) formed on the sacrificial layer and a carbonaceous membrane (e.g., 1708) further formed on the nucleation layer, according to some embodiments of the present disclosure.

The first substrate (e.g., 1702), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The first substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the first substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. For example, the first substrate may include gallium arsenic functioning as a substrate and AlGaAs functioning as a sacrificial layer that can be selectively removed later. In some other embodiments, the material of the first substrate may include magnesium oxide; sapphire; or combinations thereof.

The sacrificial layer (e.g., 1704) may be grown as a silicon oxide layer on the first substrate. The sacrificial layer may be formed over the first substrate through an oxidation process and/or a deposition process (e.g., atomic layer deposition (ALD), chemical vapor deposition (CVD), physical vapor deposition (PVD), etc.). It should be understood that any of various other oxidized sacrificial layers can be formed on the first substrate, while remaining within the scope of the present disclosure.

Upon forming the sacrificial layer, the nucleation layer (e.g., 1706), comprising one or more carbonaceous materials (e.g., poly-crystalline diamond), is formed thereon. Next, the carbonaceous membrane (e.g., 1708), comprising the one or more carbonaceous materials (e.g., poly-crystalline diamond), is further formed over the nucleation layer. In some embodiments, the nucleation layer may serve as a low quality part of the carbonaceous membrane formed thereupon. Such a carbonaceous membrane may herein be referred to as PCD membrane 1708. As shown, the PCD membrane has a bottom surface (labeled with “B”) contacting the sacrificial layer and a top surface (labeled with “T”) opposite to the bottom surface. In some other embodiments, the carbonaceous material of the PCD membrane may include a sp³ containing carbonaceous material such as, for example, monocrystalline diamond, randomly oriented diamond (such as, but not limited to, microcrystalline diamond, nanocrystalline diamond, and ultrananocrystalline diamond), diamond epilayer/film on a heteroepitaxial substrate, or a sp² containing carbonaceous material, for example, graphene or graphite, any other suitable substrate, or a combination thereof. The carbonaceous membrane may be grown on the sacrificial layer through one of various deposition processes (e.g., atomic layer deposition (ALD), chemical vapor deposition (CVD), physical vapor deposition (PVD), etc.). As mentioned above, the first substrate can be in the form of wafers, for example, having a diameter of 3 inches, 4 inches, 6 inches, 8 inches, or 12 inches, inclusive, or have any other shape or size. Accordingly, the carbonaceous membrane can have a diameter similar to the underlying first substrate.

Corresponding to operation 508, step (b) of FIG. 17 illustrates that the sacrificial layer (e.g., 1704) is removed so as to physically separate the PCD membrane (e.g., 1708) from the first substrate (e.g., 172), according to some embodiments of the present disclosure. In some embodiments, after removing the sacrificial layer, the nucleation layer may remain attached to the bottom surface of the PCD membrane. In the example where the sacrificial layer is formed of silicon oxide, the sacrificial layer may be removed through a wet etching process, for example, by applying diluted hydrofluoric acid over the workpiece. After removing the sacrificial layer, the PCD membrane may gently sit on the first substrate, i.e., with the bottom surface of the PCD membrane still facing the first substrate.

Corresponding to operation 510, step (c) of FIG. 17 illustrates that the PCD membrane (e.g., 1708), together with the nucleation layer (e.g., 1706), are flipped, according to some embodiments of the present disclosure.

Corresponding to operation 512 and the following operation 514, step (d) of FIG. 17 illustrates that the nucleation layer (e.g., 1706) is removed following removal of the first substrate (e.g., 1702), according to some embodiments of the present disclosure. In some embodiments, the nucleation layer may be removed through one or more etching processes (e.g., a reactive ion etching process).

Corresponding to operation 516, step (e) of FIG. 17 illustrates that the bottom surface of the PCD membrane (e.g., 1708) is attached to a second substrate (e.g., 1710), according to some embodiments of the present disclosure.

The second substrate (e.g., 1710), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The second substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the second substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some other embodiments, the material of the second substrate may include magnesium oxide; sapphire; or combinations thereof.

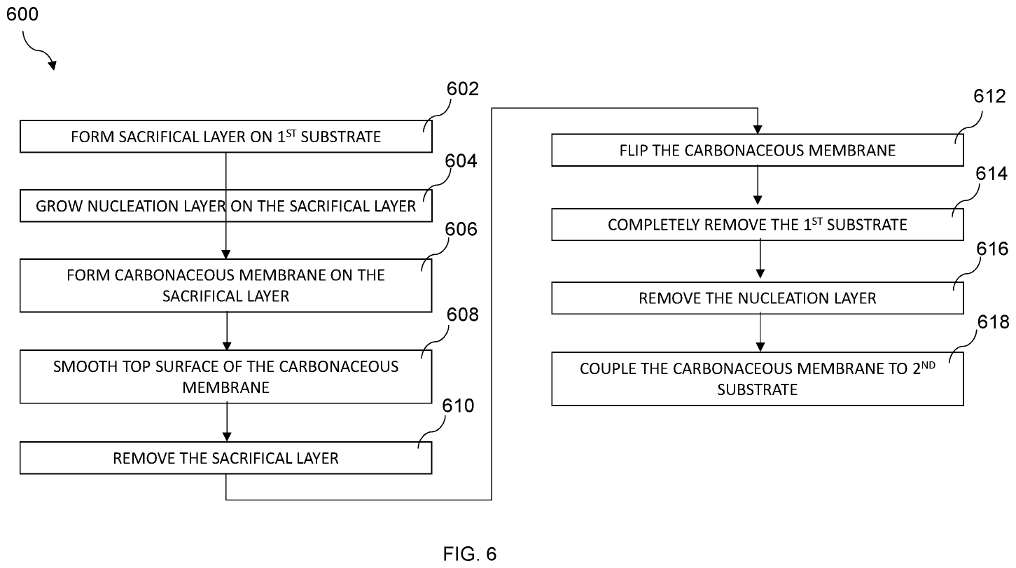

Referring next to FIG. 6, the method 600 starts with operation 602 of forming a sacrificial layer on a first substrate. The method 600 continues to operation 604 of forming a nucleation layer on the sacrificial layer. The method 600 continues to operation 606 of forming a carbonaceous membrane on the nucleation layer. The method 600 continues to operation 608 of smoothing a top surface of the carbonaceous membrane. The method 600 continues to operation 610 of removing the sacrificial layer. The method 600 continues to operation 612 of flipping the carbonaceous membrane. The method 600 continues to operation 614 of completely removing the first substrate. The method 600 continues to operation 616 of removing the nucleation layer. The method 600 continues to operation 618 of coupling the carbonaceous membrane to a second substrate.

Corresponding to operation 502 and the following operations 504 and 506, step (a) of FIG. 17 illustrates a sacrificial layer (e.g., 1704) first formed on a first substrate 1702, with a nucleation layer (e.g., 1706) formed on the sacrificial layer and a carbonaceous membrane (e.g., 1708) further formed on the nucleation layer, according to some embodiments of the present disclosure.

The first substrate (e.g., 1702), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The first substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the first substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some other embodiments, the material of the first substrate may include magnesium oxide; sapphire; or combinations thereof.

The sacrificial layer (e.g., 1704) may be grown as a silicon oxide layer on the first substrate. The sacrificial layer may be formed over the first substrate through an oxidation process and/or a deposition process (e.g., atomic layer deposition (ALD), chemical vapor deposition (CVD), physical vapor deposition (PVD), etc.). It should be understood that any of various other oxidized sacrificial layers can be formed on the first substrate, while remaining within the scope of the present disclosure.

Upon forming the sacrificial layer, the nucleation layer (e.g., 1706), comprising one or more carbonaceous materials (e.g., poly-crystalline diamond), is formed thereon. Next, the carbonaceous membrane (e.g., 1708), comprising the one or more carbonaceous materials (e.g., poly-crystalline diamond), is further formed over the nucleation layer. In some embodiments, the nucleation layer may serve as a low quality part of the carbonaceous membrane formed thereupon. Such a carbonaceous membrane may herein be referred to as PCD membrane 1708. As shown, the PCD membrane has a bottom surface (labeled with “B”) contacting the sacrificial layer and a top surface (labeled with “T”) opposite to the bottom surface. In some other embodiments, the carbonaceous material of the PCD membrane may include a sp³ containing carbonaceous material such as, for example, monocrystalline diamond, randomly oriented diamond (such as, but not limited to, microcrystalline diamond, nanocrystalline diamond, and ultrananocrystalline diamond), diamond epilayer/film on a heteroepitaxial substrate, or a sp² containing carbonaceous material, for example, graphene or graphite, any other suitable substrate, or a combination thereof. The carbonaceous membrane may be grown on the sacrificial layer through one of various deposition processes (e.g., atomic layer deposition (ALD), chemical vapor deposition (CVD), physical vapor deposition (PVD), etc.). As mentioned above, the first substrate can be in the form of wafers, for example, having a diameter of 3 inches, 4 inches, 6 inches, 8 inches, or 12 inches, inclusive, or have any other shape or size. Accordingly, the carbonaceous membrane can have a diameter similar to the underlying first substrate.

Corresponding to operation 508, step (b) of FIG. 17 illustrates that the sacrificial layer (e.g., 1704) is removed so as to physically separate the PCD membrane (e.g., 1708) from the first substrate (e.g., 1702), according to some embodiments of the present disclosure. In some embodiments, after removing the sacrificial layer, the nucleation layer may remain attached to the bottom surface of the PCD membrane. In the example where the sacrificial layer is formed of silicon oxide, the sacrificial layer may be removed through a wet etching process, for example, by applying diluted hydrofluoric acid over the workpiece. After removing the sacrificial layer, the PCD membrane may gently sit on the first substrate, i.e., with the bottom surface of the PCD membrane still facing the first substrate.

Corresponding to operation 510, step (c) of FIG. 17 illustrates that the PCD membrane (e.g., 1708), together with the nucleation layer (e.g., 1706), are flipped, according to some embodiments of the present disclosure.

Corresponding to operation 512 and the following operation 514, step (d) of FIG. 17 illustrates that the nucleation layer (e.g., 1706) is removed following removal of the first substrate (e.g., 1702), according to some embodiments of the present disclosure. In some embodiments, the nucleation layer may be removed through one or more etching processes (e.g., a reactive ion etching process).

Corresponding to operation 516, step (e) of FIG. 17 illustrates that the bottom surface of the PCD membrane (e.g., 1708) is attached to a second substrate (e.g., 1710), according to some embodiments of the present disclosure.

The second substrate (e.g., 1710), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The second substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the second substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. For example, the first substrate may include gallium arsenic functioning as a substrate and AlGaAs functioning as a sacrificial layer that can be selectively removed later. In some other embodiments, the material of the second substrate may include magnesium oxide; sapphire; or combinations thereof.

Corresponding to operation 602 and the following operations 604 and 606, step (a) of FIG. 18 illustrates a sacrificial layer (e.g., 1804) first formed on a first substrate 1802, with a nucleation layer (e.g., 1806) formed on the sacrificial layer and a carbonaceous membrane (e.g., 1808) further formed on the nucleation layer, according to some embodiments of the present disclosure.

The first substrate (e.g., 1802), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The first substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the first substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. For example, the first substrate may include gallium arsenic functioning as a substrate and AlGaAs functioning as a sacrificial layer that can be selectively removed later. In some other embodiments, the material of the first substrate may include magnesium oxide; sapphire; or combinations thereof.

The sacrificial layer (e.g., 1804) may be grown as a silicon oxide layer on the first substrate. The sacrificial layer may be formed over the first substrate through an oxidation process and/or a deposition process (e.g., atomic layer deposition (ALD), chemical vapor deposition (CVD), physical vapor deposition (PVD), etc.). It should be understood that any of various other oxidized sacrificial layers can be formed on the first substrate, while remaining within the scope of the present disclosure.

Upon forming the sacrificial layer, the nucleation layer (e.g., 1806), comprising one or more carbonaceous materials (e.g., poly-crystalline diamond), is formed thereon. Next, the carbonaceous membrane (e.g., 1808), comprising the one or more carbonaceous materials (e.g., poly-crystalline diamond), is further formed over the nucleation layer. In some embodiments, the nucleation layer may serve as a low quality part of the carbonaceous membrane formed thereupon. Such a carbonaceous membrane may herein be referred to as PCD membrane 1808. As shown, the PCD membrane has a bottom surface (labeled with “B”) contacting the sacrificial layer and a top surface (labeled with “T”) opposite to the bottom surface. In some other embodiments, the carbonaceous material of the PCD membrane may include a sp³ containing carbonaceous material such as, for example, monocrystalline diamond, randomly oriented diamond (such as, but not limited to, microcrystalline diamond, nanocrystalline diamond, and ultrananocrystalline diamond), diamond epilayer/film on a heteroepitaxial substrate, or a sp² containing carbonaceous material, for example, graphene or graphite, any other suitable substrate, or a combination thereof. The carbonaceous membrane may be grown on the sacrificial layer through one of various deposition processes (e.g., atomic layer deposition (ALD), chemical vapor deposition (CVD), physical vapor deposition (PVD), etc.). As mentioned above, the first substrate can be in the form of wafers, for example, having a diameter of 3 inches, 4 inches, 6 inches, 8 inches, or 12 inches, inclusive, or have any other shape or size. Accordingly, the carbonaceous membrane can have a diameter similar to the underlying first substrate.

Corresponding to operation 608, step (b) of FIG. 18 illustrates that the top surface of the PCD membrane (e.g., 1808) is smoothed, according to some embodiments of the present disclosure. In some embodiments, the top surface of the PCD membrane may be smoothed through one or more polishing (e.g., CMP) processes.

Corresponding to operation 610, step (c) of FIG. 18 illustrates that the sacrificial layer (e.g., 1804) is removed so as to physically separate the PCD membrane (e.g., 1808) from the first substrate (e.g., 1802), according to some embodiments of the present disclosure. In some embodiments, after removing the sacrificial layer, the nucleation layer may remain attached to the bottom surface of the PCD membrane. In the example where the sacrificial layer is formed of silicon oxide, the sacrificial layer may be removed through a wet etching process, for example, by applying diluted hydrofluoric acid over the workpiece. After removing the sacrificial layer, the PCD membrane may gently sit on the first substrate, i.e., with the bottom surface of the PCD membrane still facing the first substrate.

Corresponding to operation 612, step (d) of FIG. 18 illustrates that the PCD membrane (e.g., 1808), together with the nucleation layer (e.g., 1806), are flipped, according to some embodiments of the present disclosure.

Corresponding to operation 614 and the following operation 616, step (d) of FIG. 18 illustrates that the nucleation layer (e.g., 1806) is removed following removal of the first substrate (e.g., 1802), according to some embodiments of the present disclosure. In some embodiments, the nucleation layer may be removed through one or more etching processes (e.g., a reactive ion etching process).

Corresponding to operation 616, step (e) of FIG. 18 illustrates that the top, smoothed surface of the PCD membrane (e.g., 1808) is attached to a second substrate (e.g., 1810), according to some embodiments of the present disclosure.

The second substrate (e.g., 1810), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The second substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the second substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. For example, the first substrate may include gallium arsenic functioning as a substrate and AlGaAs functioning as a sacrificial layer that can be selectively removed later. In some other embodiments, the material of the second substrate may include magnesium oxide; sapphire; or combinations thereof.

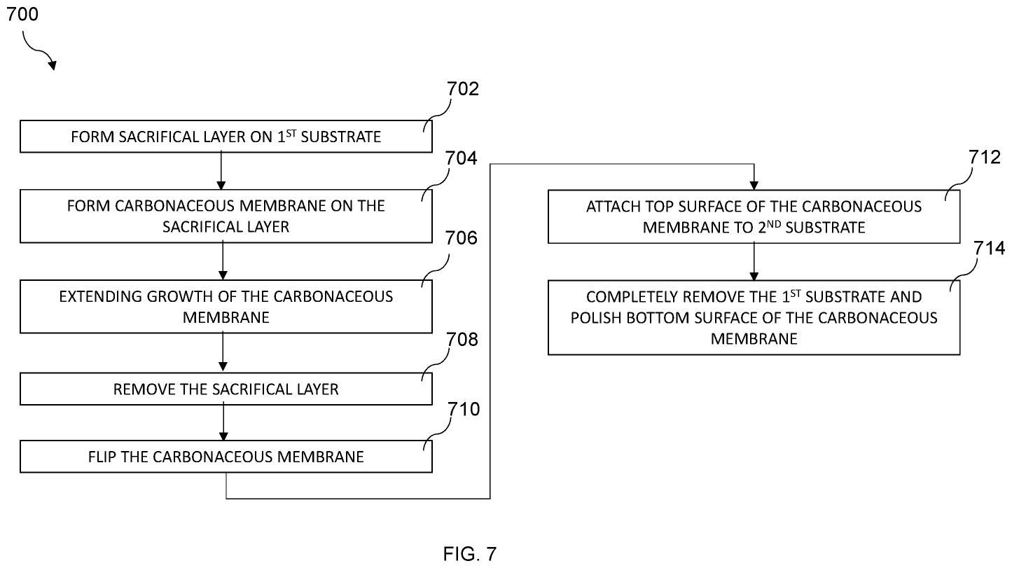

Referring then to FIG. 7, the method 700 starts with operation 702 of forming a sacrificial layer on a first substrate. The method 700 continues to operation 704 of forming a carbonaceous membrane on the sacrificial layer. The method 700 continues to operation 706 of extending growth of the carbonaceous membrane. The method 700 continues to operation 708 of removing the sacrificial layer. The method 700 continues to operation 710 of flipping the carbonaceous membrane. The method 700 continues to operation 712 of attaching a top surface of the carbonaceous membrane to a second substrate. The method 700 continues to operation 714 of completely removing the first substrate and polishing a bottom surface of the carbonaceous membrane.

Corresponding to operation 702 and the following operation 704, step (a) of FIG. 19 illustrates a carbonaceous membrane (e.g., 1906) formed on a first substrate (e.g., 1902) with a sacrificial layer (e.g., 1904) disposed therebetween, according to some embodiments of the present disclosure.

The first substrate (e.g., 1902), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The first substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the first substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. For example, the first substrate may include gallium arsenic functioning as a substrate and AlGaAs functioning as a sacrificial layer that can be selectively removed later. In some other embodiments, the material of the first substrate may include magnesium oxide; sapphire; or combinations thereof.

The sacrificial layer (e.g., 1904) may be grown as a silicon oxide layer on the first substrate. The sacrificial layer may be formed over the first substrate through an oxidation process and/or a deposition process (e.g., atomic layer deposition (ALD), chemical vapor deposition (CVD), physical vapor deposition (PVD), etc.). It should be understood that any of various other oxidized sacrificial layers can be formed on the first substrate, while remaining within the scope of the present disclosure.

Upon forming the sacrificial layer, the carbonaceous membrane (e.g., 1906), comprising one or more carbonaceous materials (e.g., poly-crystalline diamond), is further formed over the sacrificial layer. Such a carbonaceous membrane may herein be referred to as PCD membrane 1906. As shown, the PCD membrane has a bottom surface (labeled with “B”) contacting the sacrificial layer and a top surface (labeled with “T”) opposite to the bottom surface. In some other embodiments, the carbonaceous material of the PCD membrane may include a sp³ containing carbonaceous material such as, for example, monocrystalline diamond, randomly oriented diamond (such as, but not limited to, microcrystalline diamond, nanocrystalline diamond, and ultrananocrystalline diamond), diamond epilayer/film on a heteroepitaxial substrate, or a sp² containing carbonaceous material, for example, graphene or graphite, any other suitable substrate, or a combination thereof. The carbonaceous membrane may be grown on the sacrificial layer through one of various deposition processes (e.g., atomic layer deposition (ALD), chemical vapor deposition (CVD), physical vapor deposition (PVD), etc.). As mentioned above, the first substrate can be in the form of wafers, for example, having a diameter of 3 inches, 4 inches, 6 inches, 8 inches, or 12 inches, inclusive, or have any other shape or size. Accordingly, the carbonaceous membrane can have a diameter similar to the underlying first substrate.

Corresponding to operation 706, step (b) of FIG. 19 illustrates that growth of the PCD membrane (e.g., 1906) is extended, according to some embodiments of the present disclosure. As such, the PCD membrane can be formed to have a relatively thick thickness. Further, by increasing the thickness of the PCD membrane, a grain size of the PCD membrane can increases from the bottom surface to the top surface, as shown in FIG. 19.

Corresponding to operation 708, step (c) of FIG. 19 illustrates that the sacrificial layer (e.g., 1904) is removed so as to physically separate the PCD membrane (e.g., 1906) from the first substrate (e.g., 1902), according to some embodiments of the present disclosure. In the example where the sacrificial layer is formed of silicon oxide, the sacrificial layer may be removed through a wet etching process, for example, by applying diluted hydrofluoric acid over the workpiece. After removing the sacrificial layer, the PCD membrane may gently sit on the first substrate, i.e., with the bottom surface of the PCD membrane still facing the first substrate.

Corresponding to operation 710 and the following operation 712, step (d) of FIG. 19 illustrates that the PCD membrane (e.g., 1906), together with the first substrate (not shown), are flipped and are coupled to a second substrate (e.g., 1908), according to some embodiments of the present disclosure. As shown in FIG. 19, the top surface of the PCD membrane is attached to the second substrate. Stated another way, the grain size of the PCD membrane closer to the second substrate may be greater than the grain size of the PCD membrane farther away from the second substrate.

The second substrate (e.g., 1908), which is sometimes referred to as a host substrate, may be a semiconductor substrate, such as a bulk semiconductor, a semiconductor-on-insulator (SOI) substrate, or the like, which may be doped (e.g., with a p-type or an n-type dopant) or undoped. The second substrate may be a wafer, such as a silicon wafer. Generally, an SOI substrate includes a layer of a semiconductor material formed on an insulator layer. The insulator layer which is called a buried oxide (BOX) layer may be, for example, a silicon dioxide layer or a silicon mono-oxide layer, or a silicon nitride layer or the like. The insulator layer is provided on a substrate, typically a silicon or glass substrate. Other substrates, such as a multi-layered or gradient substrate may also be used. In some embodiments, the semiconductor material of the second substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. For example, the first substrate may include gallium arsenic functioning as a substrate and AlGaAs functioning as a sacrificial layer that can be selectively removed later. In some other embodiments, the material of the second substrate may include magnesium oxide; sapphire; or combinations thereof.

Corresponding to operation 714, step (e) of FIG. 19 illustrates that the first substrate (e.g., 1902) is removed, followed by polishing the PCD membrane (e.g., 1906) from its bottom surface, according to some embodiments of the present disclosure. The PCD membrane may be polished to a desired thickness through a CMP process. In this way, a PCD membrane having its grain size relatively large while uniformly distributed can be formed.

As used herein, the singular forms “a”, “an” and “the” include plural referents unless the context clearly dictates otherwise. Thus, for example, the term “a member” is intended to mean a single member or a combination of members, “a material” is intended to mean one or more materials, or a combination thereof.

As used herein, the terms “about” and “approximately” generally mean plus or minus 10% of the stated value. For example, about 0.5 would include 0.45 and 0.55, about 10 would include 9 to 11, about 1000 would include 900 to 1100.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

The terms “coupled,” “connected,” and the like as used herein mean the joining of two members directly or indirectly to one another. Such joining may be stationary (e.g., permanent) or moveable (e.g., removable or releasable). Such joining may be achieved with the two members or the two members and any additional intermediate members being integrally formed as a single unitary body with one another or with the two members or the two members and any additional intermediate members being attached to one another.

It is important to note that the construction and arrangement of the various exemplary embodiments are illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Other substitutions, modifications, changes and omissions may also be made in the design, operating conditions and arrangement of the various exemplary embodiments without departing from the scope of the present invention.

While this specification contains many specific implementation details, these should not be construed as limitations on the scope of any inventions or of what may be claimed, but rather as descriptions of features specific to particular implementations of particular inventions. Certain features described in this specification in the context of separate implementations can also be implemented in combination in a single implementation. Conversely, various features described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings and tables in a particular order, this should not be understood as requiring that such operations be performed in the particular order shown or in sequential order, or that all illustrated operations be performed, to achieve desirable results. Thus, particular implementations of the invention have been described. Other implementations are within the scope of the following claims. In some cases, the actions recited in the claims can be performed in a different order and still achieve desirable results.

What is claimed is:

1. A method for providing a carbonaceous membrane, comprising:
forming a sacrificial layer on a first substrate;
forming a carbonaceous membrane on the sacrificial layer;
removing the sacrificial layer, with a first surface of the carbonaceous membrane still facing the first substrate;
completely removing the first substrate from the carbonaceous membrane; and
coupling the carbonaceous membrane to a second substrate.

2. The method of claim 1, further comprising:
attaching the first surface of the carbonaceous membrane to the second substrate.

3. The method of claim 2, prior to attaching the first surface of the carbonaceous membrane to the second substrate, further comprising:
doping one or more regions of the carbonaceous membrane that are disposed along its opposite second surface.

4. The method of claim 2, prior to attaching the first surface of the carbonaceous membrane to the second substrate, further comprising:
etching one or more regions of the carbonaceous membrane that are disposed along its opposite second surface.

5. The method of claim 1, further comprising:
flipping the carbonaceous membrane together with the first substrate;
attaching a second surface of the carbonaceous membrane to the second substrate, the second surface being opposite to the first surface; and
removing the first substrate.

6. The method of claim 5, prior to flipping the carbonaceous membrane, further comprising:
doping one or more regions of the carbonaceous membrane that are disposed along the second surface.

7. The method of claim 5, prior to flipping the carbonaceous membrane, further comprising:
etching one or more regions of the carbonaceous membrane that are disposed along the second surface.

8. The method of claim 5, subsequently to removing the first substrate, further comprising:
doping one or more regions of the carbonaceous membrane that are disposed along the first surface.

9. The method of claim 5, subsequently to removing the first substrate, further comprising:
etching one or more regions of the carbonaceous membrane that are disposed along the first surface.

10. The method of claim 1, further comprising:
growing a nucleation layer between the sacrificial layer and the carbonaceous membrane;
subsequently to removing the sacrificial layer, flipping the carbonaceous membrane together with the nucleation layer; and
removing the nucleation layer.

11. The method of claim 1, further comprising:
growing a nucleation layer between the sacrificial layer and the carbonaceous membrane;
smoothing a second surface of the carbonaceous membrane, followed by removing the sacrificial layer, wherein the second surface is opposite to the first surface;
flipping the carbonaceous membrane together with the nucleation layer; and
removing the nucleation layer.

12. The method of claim 1, further comprising:
increasing a thickness of the carbonaceous membrane on the sacrificial layer to form the carbonaceous membrane having a grain size that increases from the first surface to its opposite second surface;
flipping the carbonaceous membrane together with the first substrate;
attaching the second surface of the carbonaceous membrane to the second substrate;
removing the first substrate; and
thinning down the carbonaceous membrane from its first surface.

13. The method of claim 1, wherein the carbonaceous membrane includes a material selected from the group consisting of: a sp³ containing carbonaceous material, the sp³ containing carbonaceous material comprising at least one of a monocrystalline diamond, a randomly oriented diamond, a polycrystalline diamond, a microcrystalline diamond, nanocrystalline diamond, a ultrananocrystalline diamond, a diamond epilayer/film on a heteroepitaxial substrate, and combination thereof.

14. A method for providing a carbonaceous membrane, comprising:
forming a sacrificial layer on a first substrate;
forming a carbonaceous membrane on the sacrificial layer, with a bottom surface of the carbonaceous membrane in contact with the sacrificial layer;
removing the sacrificial layer;
completely removing the first substrate from the carbonaceous membrane; and
attaching the bottom surface of the carbonaceous membrane to a second substrate.

15. The method of claim 14, wherein the carbonaceous membrane includes a material selected from the group consisting of: a sp³ containing carbonaceous material, the sp³ containing carbonaceous material comprising at least one of a monocrystalline diamond, a randomly oriented diamond, a polycrystalline diamond, a microcrystalline diamond, nanocrystalline diamond, a ultrananocrystalline diamond, a diamond epilayer/film on a heteroepitaxial substrate, and combination thereof.

16. The method of claim 14, further comprising:
forming a doped or etched region along a top surface of the carbonaceous membrane.

17. A method for providing a carbonaceous membrane, comprising:
forming a sacrificial layer on a first substrate;
forming a carbonaceous membrane on the sacrificial layer, with a bottom surface of the carbonaceous membrane in contact with the sacrificial layer;
removing the sacrificial layer;
flipping the carbonaceous membrane;
attaching a top surface of the carbonaceous membrane to a second substrate; and
completely removing the first substrate from the carbonaceous membrane.

18. The method of claim 17, wherein the carbonaceous membrane includes a material selected from the group consisting of: a sp³ containing carbonaceous material, the sp³ containing carbonaceous material comprising at least one of a monocrystalline diamond, a randomly oriented diamond, a polycrystalline diamond, a microcrystalline diamond, nanocrystalline diamond, a ultrananocrystalline diamond, a diamond epilayer/film on a heteroepitaxial substrate, and combination thereof.

19. The method of claim 17, prior to flipping the carbonaceous membrane, further comprising:
forming a doped or etched region along the top surface of the carbonaceous membrane.

20. The method of claim 19, further comprising:
forming a doped or etched region along a bottom surface of the carbonaceous membrane.
